(19) United States
(12) Patent Application Publication
(10) Pub. No.: US 2026/0046997 A1
(43) Pub. Date: Feb. 12, 2026

(54) HEAT DISSIPATION APPARATUS FOR VEHICLE CONTROLLER AND CONTROLLING METHOD THEREFOR

(71) Applicant: Hyundai Mobis Co., Ltd., Seoul (KR)

(72) Inventor: Min Kwon KANG, Gunpo-si (KR)

(73) Assignee: Hyundai Mobis Co., Ltd., Seoul (KR)

(21) Appl. No.: 19/225,498

(22) Filed: Jun. 2, 2025

(30) Foreign Application Priority Data
Aug. 12, 2024 (KR) 10-2024-0107475

(51) Int. Cl. H05K 1/02; H05K 7/20

(52) U.S. Cl. CPC H05K 1/0203; H05K 7/202; H05K 7/20209; H05K 7/20254; H05K 7/20263; H05K 7/20281

(57) ABSTRACT

A heat dissipation apparatus for a vehicle controller includes: a cooling system to selectively use one of an air-cooling type and a water-cooling type to remove heat generated from the controller; a cover top configured such that a coolant according to any one of the air-cooling type and the water-cooling type flows therein based on temperature of heat generated from a central processing unit; an inlet channel to transmit the coolant to an inlet hole formed at the cover top from the cooling system; an outlet channel that allows the coolant discharged through an outlet hole through the inside of the cover top to flow into a cooling device; a temperature sensor on the PCB to sense temperature of the central processing unit; and an electric open/close valve disposed in the inlet channel and the outlet channel and being opened or closed based on whether the temperature sensor senses temperature.

### CROSS-REFERENCE TO RELATED APPLICATION

This application claims the benefit of and priority to Korean Patent Application No. 10-2024-0107475, filed on Aug. 12, 2024, the entire disclosure(s) of which is hereby incorporated herein by reference in its entirety.

### TECHNICAL FIELD

The present disclosure relates to a heat dissipation apparatus for a vehicle controller and a method of controlling the heat dissipation apparatus.

### BACKGROUND

The description of this part only provides the background information of the present disclosure without configuring the related art.

Controllers that are applied to vehicles are generally formed on the basis of a box shape.

Controllers that are applied to vehicles have a cooling structure to dissipate heat that is generated by elements. The cooling structure of controllers may be designed by selecting any one type of an air-cooling structure and a water-cooling structure.

However, controllers according to the related art have increased heat generation due to the use of high-specification circuit components as the functionality becomes more advanced. To maintain stable performance, it is necessary to manage the junction temperature of each component below a specific level, and separate structure must be applied depending on the required heat dissipation performance, using heat sinks, cooling fans, etc.

Further, in the case of automotive controllers, when there is a difference in heat generation within the same controller, there is a limitation in applying a heat dissipation structure on the basis of a high-specification controller. This is because applying a heat dissipation structure based on a low-specification controller fails to satisfy the heat dissipation performance of a high-specification controller.

Further, in the case of a water-cooling structure among cooling structures, there is a problem in that it is difficult to apply it to an internal combustion engine. This is because moisture can enter a controller and potentially cause malfunction.

### SUMMARY

Accordingly, the present disclosure has been made in an effort to solve the problems described above and a main object is to selectively use an air-cooling type or a water-cooling type to dissipate heat that is generated by the elements in a controller.

Further, a main object of the present disclosure is to select a required heat dissipation structure on the basis of application of a low-specification controller and a high-specification controller.

Further, a main object of the present disclosure is to provide a dual cooling structure that is mounted on both of an internal combustion engine vehicle and an electric vehicle.

Further, a main object of the present disclosure is to provide effective heat dissipation by converting a heat dissipation structure into a water-cooling structure before a central processing unit reaches a junction temperature by automatically selecting or converting the heat dissipation structure on the basis of overload conditions of the central processing unit.

Further, a main object of the present disclosure is to improve vulnerability to moisture ingress from the outside by dissipating heat from a controller using an air-cooling coolant or a water-cooling coolant flowing through a cooling channel of a cover top.

The objects of the present disclosure are not limited to the objects described above and other objects will be clearly understood by those skilled in the art from the following description.

According to an embodiment, the heat dissipation apparatus for a vehicle controller has an effect that it is possible to selectively use an air-cooling type or a water-cooling type to dissipate heat generated from elements in the controller.

According to an embodiment, the heat dissipation apparatus for a vehicle controller has an effect that it is possible to select a required heat dissipation structure on the basis of application of a low-specification controller and a high-specification controller.

According to an embodiment, the heat dissipation apparatus for a vehicle controller has an effect that it is possible to provide a dual cooling structure that is mounted in both of internal combustion engine vehicle and an electric vehicle.

According to an embodiment, the heat dissipation apparatus for a vehicle controller has an effect that it is possible to provide effective heat dissipation by converting a heat dissipation structure into a water-cooling structure before a central processing unit reaches a junction temperature by automatically selecting or converting the heat dissipation structure on the basis of overload conditions of the central processing unit.

According to an embodiment, the heat dissipation apparatus for a vehicle controller has an effect that it is possible to improve vulnerability to moisture ingress from the outside by dissipating heat from a controller using an air-cooling coolant or a water-cooling coolant flowing through a cooling channel of a cover top.

In one general aspect, a heat dissipation apparatus for a vehicle controller includes: a cooling system configured to selectively use any one of an air-cooling type and a water-cooling type to remove heat generated from the controller; a cover top configured such that a coolant from any one of the air-cooling type and the water-cooling type flows therein based on temperature of heat generated from a central processing unit disposed on a PCB of the controller; an inlet channel configured to transmit the coolant to an inlet hole formed at the cover top from the cooling system; an outlet channel configured such that the coolant discharged through an outlet hole through the inside of the cover top flows into a cooling device of the cooling system; a temperature sensor mounted on the PCB and configured to sense temperature of the central processing unit; and an electric open/close valve disposed in each of the inlet channel and the outlet channel and configured to be opened or closed based on whether the temperature sensor senses temperature.

The cooling device may include an air-cooling cooling device composed of an air-cooled evaporator based on the air-cooling type and a blow motor and a water-cooling cooling device composed of a water-cooling heatsink based on the water-cooling type and a pump.

The cover top may include: a water/air-cooling heat dissipation section including a cooling channel continuously curving from the inlet hole to the outlet hole; and heat dissipation fins disposed in an area in an upward direction.

The inlet channel may diverge from the inlet hole to an exhaust port of the air-cooling cooling device and a water outlet of the water-cooling cooling device.

The outlet channel may diverge from the outlet hole to an intake port of the air-cooling cooling device and a water inlet of the water-cooling cooling device.

The outlet channel may include: a radiator configured to cool the coolant discharged through the outlet hole after passing through the cover top; a compressor configured to cool the coolant based on the air-cooling type; and a chiller configured to cool the coolant based on the water-cooling type.

The electric open/close valve may include: a first electric open/close valve disposed at a divergence point of the exhaust port of the air-cooling cooling device and the water outlet of the water-cooling cooling device in the inlet channel; and a second electric open/close valve receiving the coolant simultaneously from the compressor and the chiller and disposed at a divergence point of the intake port of the air-cooling cooling device and the water inlet of the water-cooling cooling device in the outlet channel.

The cooling system may open or close the first electric open/close valve and the second electric open/close valve based on whether temperature sensed by the temperature sensor is over a critical temperature.

The cooling system, when it is determined that temperature sensed by the temperature sensor is over the critical temperature, may control the first electric open/close valve such that the coolant provided from a water outlet of the water-cooling cooling device and control the second electric open/close valve such that the coolant passing through the cover top flows into the water inlet of the water-cooling cooling device through the radiator and the chiller.

In another general aspect, a method of operating the heat dissipation apparatus includes: a process of sensing temperature of the central processing unit in the controller by the temperature sensor based on whether the controller operates; a process of selectively opening or closing the electric open/close valves such that the coolant according to the air-cooling type of the cooling system flows into the inlet hole of the cover top; a process of determining whether temperature of the central processing unit is over a critical temperature; and a process of selectively opening or closing the electric open/close valves such that the coolant from the water-cooling type of the cooling system flows into the inlet hole of the cover top when it is determined that the temperature of the central processing unit is over the critical temperature.

### BRIEF DESCRIPTION OF THE DRAWINGS

FIG. 1 is an exploded perspective view showing the configuration of a controller according to an embodiment of the present disclosure.

FIG. 2 is a vertical cross-sectional view taken along line B-B in FIG. 1 to show in detail a cover top and a PCB according to an embodiment of the present disclosure.

FIG. 3 is a cross-sectional view taken along line A-A in FIG. 1.

FIG. 4 is a view showing the configuration of a vehicle equipped with a heat dissipation apparatus for a vehicle controller according to an embodiment of the present disclosure.

FIG. 5 is a flowchart showing of a method of controlling the heat dissipation apparatus for a vehicle controller according to an embodiment of the present disclosure.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

The following detailed description, together with the accompanying drawings, is intended to describe exemplary embodiments of the present invention, and is not intended to represent the only embodiments in which the present invention may be practiced.

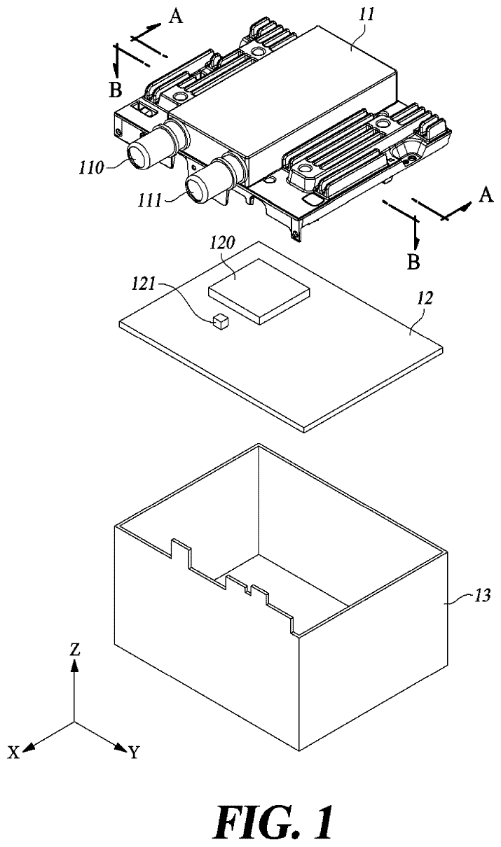

FIG. 1 is an exploded perspective view showing the configuration of a controller according to an embodiment of the present disclosure.

Referring to FIG. 1, a vehicle controller 10 according to an embodiment of the present disclosure includes some or all of a cover top 11, a PCB 12, and a main chassis 13.

The controller 10 according to an embodiment of the present disclosure may be disposed at any one position in a vehicle 50.

The cover top 11 may be disposed on the upper end of the controller 10.

The cover top 11 may be made of a material for dissipating heat, which is generated from the PCB 12 disposed at the lower end, to the outside. For example, the material of the cover top 11 may be an aluminum die-casting material.

The cover top 11 according to an embodiment of the present disclosure may be configured such that an air-cooling coolant or a water-cooling coolant passes through it. In this case, air, nitrogen, helium, argon, hydrogen, carbon dioxide, and the like may be used as the air-cooling coolant. As the water-cooling coolant, water, ethylene glycol, propylene glycol, oil, refrigerants, brine, synthetic heat transfer fluid, diethylene glycol, and the like may be used.

The cover top 11 includes an inlet hole 111 and an outlet hole 110.

For the inlet hole 111 and the outlet hole 110, connectors for connection with an inlet channel 90 and an outlet channel 92 may be disposed.

An air-cooling coolant or a water-cooling coolant may flow into the inlet hole 111.

An air-cooling coolant or a water-cooling coolant flowing from the inlet hole 111 can be discharged through the outlet hole 110 after passing through the cover top 11.

The PCB 12 may be disposed at the lower end of the cover top 11. The PCB 12 may be accommodated in an accommodation space of the main chassis to be described below.

A central processing unit 120 and a temperature sensor 121 may be mounted on the PCB 12.

The central processing unit 120 according to an embodiment is a component that processes data and executes instructions in an Electronic Control Unit (ECU) of the vehicle 50. The central processing unit 120 is configured to analyze data input from sensors and control operation of the vehicle on the basis of the analyzed data.

The central processing unit 120 requires high computing performance because it has to process various sensor data in real time.

The central processing unit 120 according to an embodiment may have a high specification or a low specification. When the central processing unit 120 has a high specification, it may include a high clock speed and a large amount of computation ability. The higher the clock speed, the larger the amount of processing instructions per unit time, but this also consumes more power and generates higher amounts of heat. On the other hand, when the central processing unit 120 has a low specification, it has relatively low clock speed and computation ability. Accordingly, a low specification consumes less power and generates less heat compared to a high specification.

The vehicle controller 10 according to an embodiment can select effective heat dissipation in an air-cooling type or a water-cooling type on the basis of the temperature of the central processing unit 120 regardless of the specification of the central processing unit 120.

The temperature sensor 121 senses the temperature of the central processing unit 120.

The temperature sensor 121 may be mounted and disposed on the PCB 12 with the central processing unit 120. The temperature sensor 121 may be directly attached to the surface of the central processing unit. The temperature sensor 121 may be disposed at a position at which the cover top 11 and the central processing unit 120 are in contact with each other or to which they are adjacent.

As the temperature sensor 121 according to an embodiment, any one of a Resistance Temperature Detector (RTD), a thermistor, a thermocouple, and an integrated temperature sensor may be used.

The main chassis 13 forms an outer case of the controller 10 together with the cover top 11. The main chassis 13 includes an accommodation space for accommodating the PCB 12.

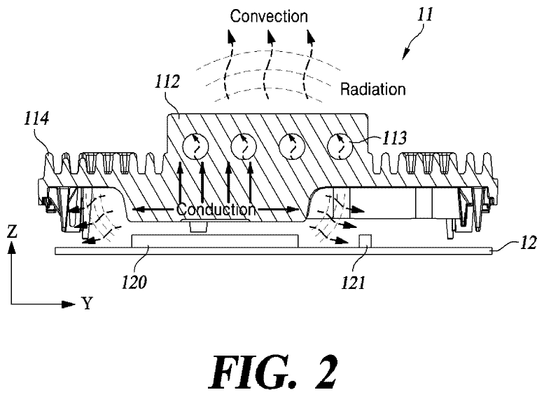

FIG. 2 is a vertical cross-sectional view taken along line B-B in FIG. 1 to show in detail a cover top and a PCB according to an embodiment of the present disclosure.

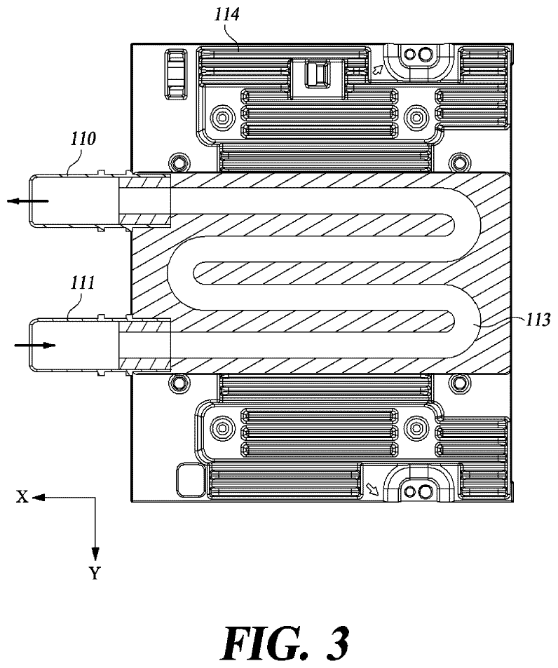

FIG. 3 is a cross-sectional view taken along line A-A in FIG. 1.

Referring to FIG. 1 to FIG. 3, the cover top 11 according to an embodiment of the present disclosure includes a water/air-cooling heat dissipation section 112, a cooling channel 113, and heat dissipation fins 114.

The water/air-cooling heat dissipation section 112 may partially protrude from the upper end of the cover top 11.

The water/air-cooling heat dissipation section 112 has an upwardly convex shape such that a water-cooling coolant or an air-cooling coolant can heat of the central processing unit 120 while passing through it.

The water/air-cooling heat dissipation section 112 may have a downwardly convex shape to be disposed adjacent to or in contact with the central processing unit 120 disposed at the lower end.

The water/air-cooling heat dissipation section 112 can dissipate heat generated from the central processing unit 120 laterally or upwardly through conduction, convection, and radiation.

For example, the water/air-cooling heat dissipation section 112 can conduct heat through direct contact with the central processing unit 120. In order to minimize thermal resistance, a thermal pad may be used between the water/air-cooling heat dissipation section 112 and the central processing unit 120.

Heat generated from the central processing unit 120 is conducted through the water/air-cooling heat dissipation section 112, whereby the heat can be distributed to the internal space of the cover top 11. Further, the cover top 11 can distribute the heat of the central processing unit 120 using the heat dissipation fins 114 on the surface of the upper end. The heat dissipation fins are configured to maximize the contact area with external air, so the heat transfer efficiency can be increased.

When the cover top 11 is heated by heat of the central processing unit 120, the surrounding air is heated while passing through the heat dissipation fins 114, and rises. Accordingly, natural convection occurs.

Further, heat can be discharged by radiation from the upper surface and the internal space of the cover top 11.

The cooling channel 113 may be formed in the water/air-cooling heat dissipation section 112. The inlet hole 111 into which a coolant flows is positioned at the start point of the cooling channel 113 and the outlet hole 110 through which a coolant is discharged is positioned at the end point. The inlet hole 111 and the outlet hole 110 are disposed at both ends of the cooling channel 113 so that a coolant can efficiently flows.

The cooling channel 113 is a channel or a pipe formed in the cover top 11 and is formed such that a coolant can absorb and discharge heat throughout the cover top 11 while flowing through the cooling channel. The cooling channel 113 is disposed at the water/air-cooling heat dissipation section 112 formed at the upper end of the cover top 11. The shape of the cooling channel 113 is not limited to that shown in FIG. 3.

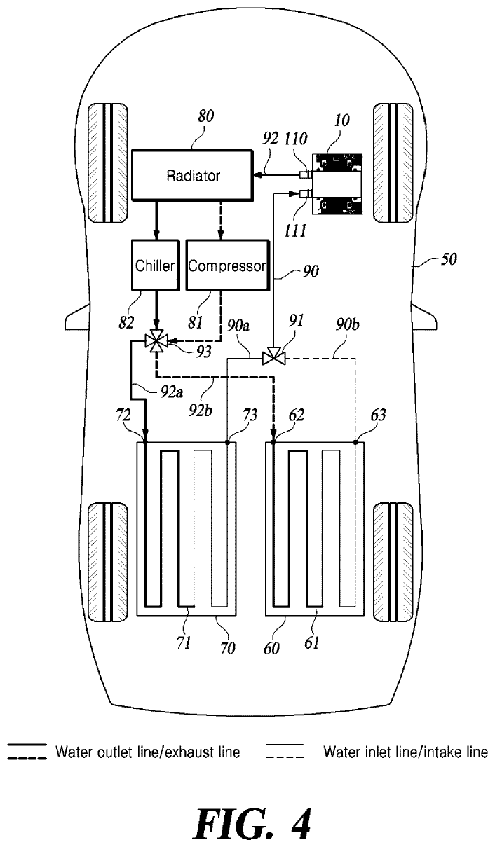

FIG. 4 is a view showing the configuration of a vehicle equipped with a heat dissipation apparatus for a vehicle controller according to an embodiment of the present disclosure.

Referring to FIG. 1 to FIG. 4, the heat dissipation apparatus for a vehicle controller 10 according to an embodiment of the present disclosure efficiently dissipates heat generated from the central processing unit 120 using a cooling system 60, 70. In this case, the cooling system 60, 70 includes an air-cooling cooling device 60 and a water-cooling cooling device 70.

The air-cooling cooling device 60 includes an air-cooling line 61. The air-cooling line 61 may be configured inside the air-cooling cooling device 60. The air-cooling line 61 can cool and discharge hot gas flowing inside from an intake port 62 of the air-cooling cooling device 60 to an exhaust port 63.

Though not shown in FIG. 4, the air-cooling cooling device 60 includes an air-cooled evaporator and a blow motor. The air-cooling cooling device 60 can cool hot gas flowing inside through the intake port 62 using the air-cooled evaporator. The air-cooling cooling device 60 can forcibly introduce cooled gas from the air-cooled evaporator into the inlet hole 111 of the cover top 11 using the blow motor.

The water-cooling cooling device 70 includes a water-cooling line 71. The water-cooling line 71 may be configured inside the water-cooling cooling device 70. The water-cooling line 71 can cool and discharge hot fluid flowing inside from water inlet 72 of the water-cooling cooling device 70 to a water outlet 73.

Though not shown in FIG. 4, the water-cooling cooling device 70 includes a water-cooling heatsink and a pump. The water-cooling cooling device 70 can cool hot fluid flowing inside from the water inlet 72 using the water-cooling heatsink. The water-cooling cooling device 70 can forcibly introduce cooled fluid from the water-cooling heatsink into the inlet hole 111 of the cover top 11 using the pump.

An inlet channel 90 according to an embodiment is configured between the exhaust port 63 of the air-cooling cooling device 60, the water outlet 73 of the water-cooling cooling device 70, and the inlet hole 111 of the cover top 11.

The inlet channel 90 according to an embodiment may be configured as a line through which an air-cooling coolant and a water-cooling coolant both can pass.

A first electric open/close valve 91 is configured in the inlet channel 90. The first electric open/close valve 91, for example, may be a three-way valve.

The inlet channel 90 may include a water inlet line 90a and an intake line 90b. For example, the water inlet line 90a can configure the line from the water outlet 73 of the water-cooling cooling device 70 to the first electric open/close valve 91. The intake line 90b can configure the line from the exhaust port 63 of the air-cooling cooling device 60 to the first electric open/close valve 91.

The first electric open/close valve 91 can open the water inlet line 90a or the intake line 90b on the basis of whether the temperature of the central processing unit 120 according to an embodiment is over a critical temperature.

An outlet channel 92 according to an embodiment is configured between the intake port 62 of the air-cooling cooling device 60 and the water inlet 72 of the water-cooling cooling device 70 from the outlet hole 110 of the cover top 11. In detail, a radiator 80, a chiller 82, a compressor 81, and a second electric open/close valve 93 may be configured in the outlet channel 92.

The radiator 80 performs a heat exchange function to cool the hot fluid or hot gas discharged from the outlet hole 110 of the cover top 11. Though not shown in FIG. 4, the radiator 80 can reduce the temperature of fluid or gas flowing therein by exchanging heat with external air through a fin structure.

The chiller 82 cools a water-cooling coolant. The water-cooling coolant decreases in temperature by exchanging hat with a refrigerant while passing through a heat exchange in the chiller 82.

The compressor 81 changes an air-cooling coolant into a high-temperature and high-pressure state by compressing the air-cooling coolant. The compressed coolant can exchange heat.

The second electric open/close valve 93 may be disposed between the chiller 82, the compressor 81, the intake port 62 of the air-cooling cooling device 60, and the water inlet 72 of the water-cooling cooling device 70. In this case, the second electric open/close valve 93 may be a four-way valve.

An out channel may include a water outlet line 92a and an exhaust line 92b. For example, the water outlet line 92a can configure the line going to the water inlet 72 of the water-cooling cooling device 70 through the chiller 82 and the second electric open/close valve 93 from the radiator 80. The exhaust line 92b can configure the line going to the intake port 62 of the air-cooling cooling device 60 through the compressor 82 and the second electric open/close valve 93 from the radiator 80.

The second electric open/close valve 93 can open the water outlet line 92a or the exhaust line 92b on the basis of whether the temperature of the central processing unit 120 according to an embodiment is over a critical temperature.

The heat dissipation apparatus for a vehicle controller 10 according to an embodiment can dissipate first the heat of the central processing unit 120 using the air-cooling cooling device 60 when the controller 10 starts operating.

In this case, in order to introduce the coolant supplied from the air-cooling cooling device 60 to the inlet hole 111 of the cover top 11, the controller 10 controls the first electric open/close valve 91 to close the water inlet line 90a and open the intake line 90b. Simultaneously, the controller 10 controls the second electric open/close valve 93 to close the water outlet line 92a and open the exhaust line 92b. In this case, the air-cooling coolant supplied from the air-cooling cooling device 60 can dissipate the heat of the central processing unit 120 while passing through the cooling channel 113 of the cover top 11.

When it is determined that the temperature of the central processing unit 120 sensed by the temperature sensor 121 exceeds the critical temperature, the controller 10 controls the first electric open/close valve 91 and the second electric open/close valve 93 to dissipate heat of the central processing unit 120 using the water-cooling cooling device 70. For example, the controller 10 controls the second first electric open/close valve 91 to close the intake line 90b and open the water outlet line 90a. Simultaneously, the controller 10 controls the second electric open/close valve 93 to close the exhaust line 92b and open the water outlet line 92a. In this case, the water-cooling coolant supplied from the water-cooling cooling device 70 can dissipate the heat of the central processing unit 120 while passing through the cooling channel 113 of the cover top 11.

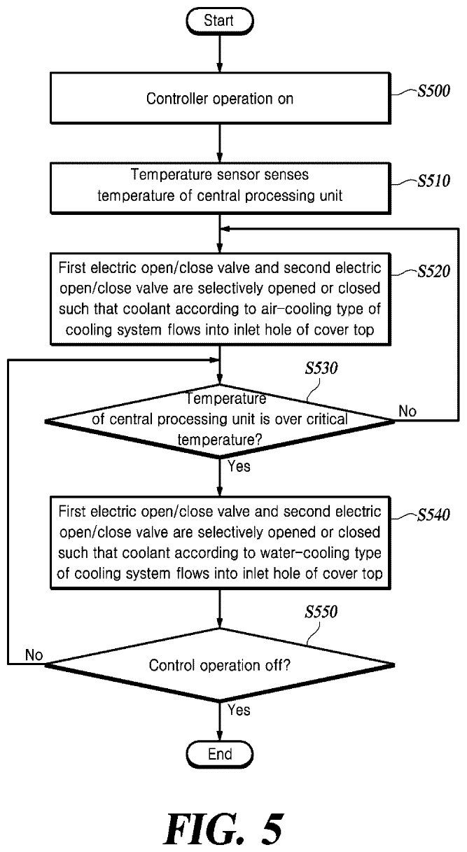

FIG. 5 is a flowchart showing of a method of controlling the heat dissipation apparatus for a vehicle controller according to an embodiment of the present disclosure.

Referring to FIG. 1 to FIG. 5, the vehicle controller 10 is activated (S500). Activation of the vehicle controller 10 according to an embodiment means that the controller 10 enters a control standby state. For example, it may mean that the controller 10 receives a key-on signal from a driver.

The temperature sensor 121 senses the temperature of the central processing unit 120 in the controller 10 on the basis of whether the controller 10 operates (S510).

The first electric open/close valve and the second electric open/close valve 93 are selectively opened or closed such that a coolant according to the air-cooling type of the cooling system 60, 70 flows into the inlet hole 111 of the cover top 11 (S520).

Whether the temperature of the central processing unit 120 is over the critical temperature is determined (S530).

In the process S530, when it is determined that the temperature of the central processing unit 120 is over the critical temperature, the first electric open/close valve 91 and the second electric open/close valve 93 are selectively opened or closed such that a coolant according to the water-cooling type of the cooling system 60, 70 flows into the inlet hole 111 of the cover top 11 (S540).

Whether the operation of the controller 10 has been inactivated is determined (S550). In the process S550, the execution state of the heat dissipation apparatus for a vehicle controller 10 according to an embodiment is finished or maintained on the basis of whether the controller 10 operates.

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

What is claimed is:

1. A heat dissipation apparatus for a vehicle controller, comprising:
a cooling system configured to selectively use any one of an air-cooling type and a water-cooling type to remove heat generated from the controller;
a cover top configured such that a coolant from any one of the air-cooling type and the water-cooling type flows therein based on temperature of heat generated from a central processing unit disposed on a PCB of the controller;
an inlet channel configured to transmit the coolant to an inlet hole formed at the cover top from the cooling system;
an outlet channel configured such that the coolant discharged through an outlet hole through the inside of the cover top flows into a cooling device of the cooling system;
a temperature sensor mounted on the PCB and configured to sense temperature of the central processing unit; and
an electric open/close valve disposed in each of the inlet channel and the outlet channel and configured to be opened or closed based on whether the temperature sensor senses temperature.

2. The heat dissipation apparatus of claim 1, wherein the cooling device includes an air-cooling cooling device composed of an air-cooled evaporator based on the air-cooling type and a blow motor and a water-cooling cooling device composed of a water-cooling heatsink based on the water-cooling type and a pump.

3. The heat dissipation apparatus of claim 1, wherein the cover top includes:
a water/air-cooling heat dissipation section including a cooling channel continuously curving from the inlet hole to the outlet hole; and
heat dissipation fins disposed in an area in an upward direction.

4. The heat dissipation apparatus of claim 2, wherein the inlet channel diverges from the inlet hole to an exhaust port of the air-cooling cooling device and a water outlet of the water-cooling cooling device.

5. The heat dissipation apparatus of claim 2, wherein the outlet channel diverges from the outlet hole to an intake port of the air-cooling cooling device and a water inlet of the water-cooling cooling device.

6. The heat dissipation apparatus of claim 5, wherein the outlet channel includes:
a radiator configured to cool the coolant discharged through the outlet hole after passing through the cover top;
a compressor configured to cool the coolant based on the air-cooling type; and
a chiller configured to cool the coolant based on the water-cooling type.

7. The heat dissipation apparatus of claim 6, wherein the electric open/close valve includes:
a first electric open/close valve disposed at a divergence point of the exhaust port of the air-cooling cooling device and the water outlet of the water-cooling cooling device in the inlet channel; and
a second electric open/close valve receiving the coolant simultaneously from the compressor and the chiller and disposed at a divergence point of the intake port of the air-cooling cooling device and the water inlet of the water-cooling cooling device in the outlet channel.

8. The heat dissipation apparatus of claim 7, wherein the cooling system opens or closes the first electric open/close valve and the second electric open/close valve based on whether temperature sensed by the temperature sensor is over a critical temperature.

9. The heat dissipation apparatus of claim 8, wherein the cooling system, when it is determined that temperature sensed by the temperature sensor is over the critical temperature, controls the first electric open/close valve such that the coolant provided from a water outlet of the water-cooling cooling device and controls the second electric open/close valve such that the coolant passing through the cover top flows into the water inlet of the water-cooling cooling device through the radiator and the chiller.

10. A method of operating the heat dissipation apparatus of claim 1, comprising:
a process of sensing temperature of the central processing unit in the controller by the temperature sensor based on whether the controller operates;
a process of selectively opening or closing the electric open/close valves such that the coolant according to the air-cooling type of the cooling system flows into the inlet hole of the cover top;
a process of determining whether temperature of the central processing unit is over a critical temperature; and
a process of selectively opening or closing the electric open/close valves such that the coolant from the water-cooling type of the cooling system flows into the inlet hole of the cover top when it is determined that the temperature of the central processing unit is over the critical temperature.
